(19) United States
(12) Patent Application Publication
(10) Pub. No.: US 2026/0082665 A1
(43) Pub. Date: Mar. 19, 2026

(54) SEMICONDUCTOR DEVICE

(71) Applicants: KABUSHIKI KAISHA TOSHIBA, Tokyo (JP); Toshiba Electronic Devices & Storage Corporation, Tokyo (JP)

(72) Inventors: Yuta SATO, Himeji Hyogo (JP); Toru SHONO, Kanazawa Ishikawa (JP)

(21) Appl. No.: 19/043,289

(22) Filed: Jan. 31, 2025

(30) Foreign Application Priority Data
Sep. 18, 2024 (JP) 2024-161272

(51) Int. Cl. H10D 64/62; H10D 30/01; H10D 30/66; H10D 64/23

(52) U.S. Cl. CPC H10D 64/62; H10D 30/0295; H10D 30/0297; H10D 30/668; H10D 64/2527

(57) ABSTRACT

According to one embodiment, a semiconductor device includes first and second electrodes, first to third semiconductor regions, and a gate electrode. The second electrode includes a contact portion. The contact portion includes first to third conductive layers. The second conductive layer is provided between the first conductive layer and the second semiconductor region and between the first conductive layer and the third semiconductor region. The third conductive layer is provided between the second conductive layer and the second semiconductor region and between the second conductive layer and the third semiconductor region. A coefficient of thermal expansion of the first conductive layer is less than that of the second conductive layer and less than that of the third conductive layer. An electrical resistivity of the second conductive layer is less than that of the first conductive layer and less than that of the third conductive layer.

### CROSS-REFERENCE TO RELATED APPLICATIONS

This application is based upon and claims the benefit of priority from Japanese Patent Application No.2024-161272, filed on Sep. 18, 2024; the entire contents of which are incorporated herein by reference.

### FIELD

Embodiments of the present invention generally relating to a semiconductor device.

### BACKGROUND

Semiconductor devices such as metal oxide semiconductor field effect transistors (MOSFETs) are used for power conversion and other applications. For semiconductor devices, there is a need for technology that can suppress the occurrence of leakage currents.

### BRIEF DESCRIPTION OF THE DRAWINGS

FIG. 1 is a perspective cross-sectional view illustrating a portion of a semiconductor device according to an embodiment;

FIG. 2 is an enlarged cross-sectional view of a portion of FIG. 1;

FIGS. 3A and 3B are cross-sectional views illustrating a method for manufacturing the semiconductor device according to the embodiment;

FIGS. 4A and 4B are cross-sectional views illustrating the method for manufacturing the semiconductor device according to the embodiment;

FIGS. 5A and 5B are cross-sectional views illustrating the method for manufacturing the semiconductor device according to the embodiment;

FIGS. 6A and 6B are cross-sectional views illustrating the method for manufacturing the semiconductor device according to the embodiment;

FIGS. 7A and 7B are cross-sectional views illustrating the method for manufacturing the semiconductor device according to the embodiment;

FIG. 8 is a cross-sectional view illustrating a portion of a semiconductor device according to a first modification of the embodiment;

FIG. 9 is a cross-sectional view illustrating a portion of the semiconductor device according to a second modification of the embodiment; and

FIG. 10 is a cross-sectional view illustrating a portion of a semiconductor device according to a third modification of the embodiment.

### DETAILED DESCRIPTION

According to one embodiment, a semiconductor device includes a first electrode, a first semiconductor region of a first conductivity type, a second semiconductor region of a second conductivity type, a third semiconductor region of the first conductivity type, a gate electrode, and a second electrode. The first semiconductor region is provided on the first electrode. The second semiconductor region is provided on the first semiconductor region. The third semiconductor region is provided on the second semiconductor region. The gate electrode faces the second semiconductor region via a first insulating layer in a second direction. The second direction is perpendicular to a first direction from the first electrode toward the first semiconductor region. The second electrode includes a contact portion that is in contact with the third semiconductor region in the second direction. The second electrode provided on the second semiconductor region and the third semiconductor region. The contact portion includes a first conductive layer, a second conductive layer, and a third conductive layer. The second conductive layer is provided between the first conductive layer and the second semiconductor region and between the first conductive layer and the third semiconductor region. The third conductive layer is provided between the second conductive layer and the second semiconductor region and between the second conductive layer and the third semiconductor region. A coefficient of thermal expansion of the first conductive layer is less than a coefficient of thermal expansion of the second conductive layer and less than a coefficient of thermal expansion of the third conductive layer. An electrical resistivity of the second conductive layer is less than an electrical resistivity of the first conductive layer and less than an electrical resistivity of the third conductive layer.

Embodiments of the invention will now be described with reference to the drawings. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated. In the drawings and the specification of the application, components similar to those described thereinabove are marked with like reference numerals, and a detailed description is omitted as appropriate.

In the following descriptions and drawings, notations of n⁺, n⁻ and p⁺, p represent relative levels of impurity concentrations in conductivity types. That is, the notation with “+” shows a relatively higher impurity concentration than an impurity concentration for the notation without any of “+” and “−”. The notation with “−” shows a relatively lower impurity concentration than the impurity concentration for the notation without any of them. These notations represent relative levels of net impurity concentrations after the mutual compensation of these impurities when respective regions include both of a p-type impurity and an n-type impurity.

The embodiments described below may be implemented by reversing the p-type and the n-type of the semiconductor regions.

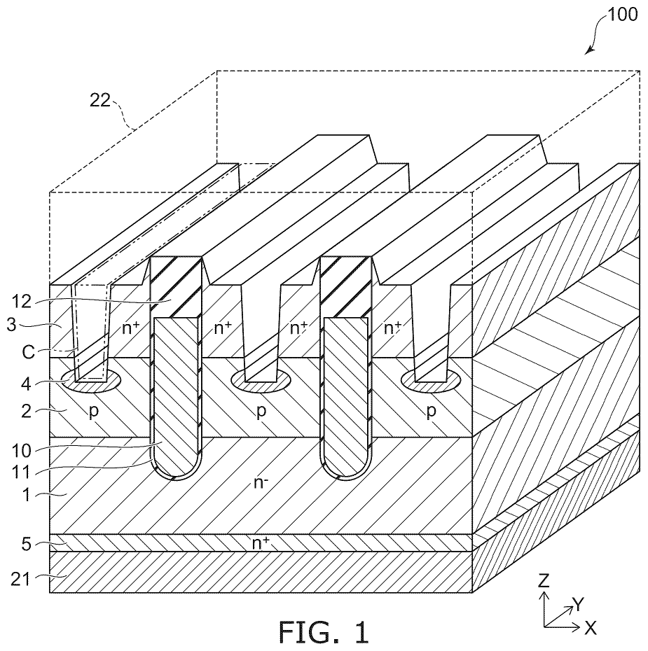

FIG. 1 is a perspective cross-sectional view illustrating a portion of a semiconductor device according to an embodiment.

The semiconductor device 100 according to the embodiment is a MOSFET. As shown in FIG. 1, the semiconductor device 100 includes an n⁻type (a first conductivity type) drift region 1 (a first semiconductor region), a p-type (a second conductivity type) base region 2 (a second semiconductor region), an n⁺-type source region 3 (a third semiconductor region), a p⁺-type contact region 4 (a fourth semiconductor region), an n⁺-type drain region 5, a gate electrode 10, a first insulating layer 11, a second insulating layer 12, a drain electrode 21 (a first electrode), and a source electrode 22 (a second electrode). In FIG. 1, the source electrode 22 is shown by a dashed line and depicted as transparent.

An XYZ orthogonal coordinate system is used in the description of the embodiments. A direction from the drain electrode 21 toward the n⁻-type drift region 1 is taken as a Z-direction (a first direction); and two mutually-orthogonal directions perpendicular to the Z-direction are taken as an X-direction (a second direction) and a Y-direction (a third direction). In the description, the direction from the drain electrode 21 toward the n⁻-type drift region 1 is called “up/upward/above/higher than”, and the opposite direction is called “down/downward/below/lower than”. These directions are based on the relative positional relationship between the drain electrode 21 and the n⁻-type drift region 1, and are independent of the direction of gravity.

The drain electrode 21 is provided on the lower surface of the semiconductor device 100. The n⁺-type drain region 5 is provided on the drain electrode 21 and is electrically connected to the drain electrode 21. The n⁻-type drift region 1 is provided on the n⁺-type drain region 5. The n⁻-type drift region 1 is electrically connected to the drain electrode 21 via the n⁺-type drain region 5. The n-type impurity concentration in the n⁻-type drift region 1 is less than the n-type impurity concentration in the n⁺-type drain region 5.

The gate electrode 10 is provided on the n⁻-type drift region 1 via the first insulating layer 11. Multiple gate electrodes 10 are provided in the X-direction, and the gate electrodes 10 are separated from each other.

The p-type base region 2 is provided between the adjacent gate electrodes 10. The p-type base region 2 is located on the n⁻-type drift region 1. The p-type base region 2 and the gate electrode 10 are alternately arranged in the X-direction. The gate electrode 10 faces the p-type base region 2 in the X-direction via the first insulating layer 11.

The n⁺-type source region 3 is provided on the p-type base region 2. The gate electrode 10 may face a portion of the n⁻-type drift region 1 and a portion of the n⁺-type source region 3 in the X-direction via the first insulating layer 11.

The source electrode 22 is provided on the p-type base region 2, the n⁺-type source region 3, and the gate electrode 10. The source electrode 22 is located on the upper surface of the semiconductor device 100 and is electrically connected to the p-type base region 2 and the n⁺-type source region 3. The second insulating layer 12 is provided between the gate electrode 10 and the source electrode 22 in the Z-direction. The source electrode 22 is electrically isolated from the gate electrode 10 by the second insulating layer 12.

The source electrode 22 includes a contact portion C. The contact portion C extends downward and, in the X-direction, is in contact with the p-type base region 2 and the n⁺-type source region 3. The p⁺-type contact region 4 is provided between the p-type base region 2 and the contact portion C. The p-type impurity concentration in the p⁺-type contact region 4 is greater than the p-type impurity concentration in the p-type base region 2.

For example, the p-type base region 2, the n⁺-type source region 3, the p⁺-type contact region 4, the gate electrode 10, and the contact portion C each extend in the Y-direction. A pair of n⁺-type source regions 3, one p⁺-type contact region 4, and one contact portion C are provided on one p-type base region 2. The p-type base region 2, the n⁺-type source region 3, the p⁺-type contact region 4, the gate electrode 10, and the contact portion C each are provided in a plurality along the X-direction, and they are arranged in a stripe pattern.

Examples of the materials of the components will now be described.

The n⁻-type drift region 1, p-type base region 2, n⁺-type source region 3, p⁺-type contact region 4, and the n⁺-type drain region 5 include silicon, silicon carbide, gallium nitride, or gallium arsenide as a semiconductor material. When silicon is used as the semiconductor material, arsenic, phosphorus, or antimony can be used as the n-type impurity. As a p-type impurity, boron can be used. The gate electrode 10 includes a conductive material such as polysilicon. The first insulating layer 11 and the second insulating layer 12 include an insulating material such as silicon oxide, silicon nitride, or silicon oxynitride. The drain electrode 21 and the source electrode 22 include a metal material.

Operations of the semiconductor device 100 will now be described. A voltage that is not less than a threshold is applied to the gate electrode 10 in a state in which a positive voltage with respect to the source electrode 22 is applied to the drain electrode 21. As a result, a channel (an inversion layer) is formed in the p-type base region 2. Electrons flow from the source electrode 22 toward the n⁻-type drift region 1 via the channel; and the semiconductor device 100 is set to an on-state. Subsequently, when the voltage applied to the gate electrode 10 drops below the threshold, the channel in the p-type base region 2 disappears, and the semiconductor device 100 is set to an off-state.

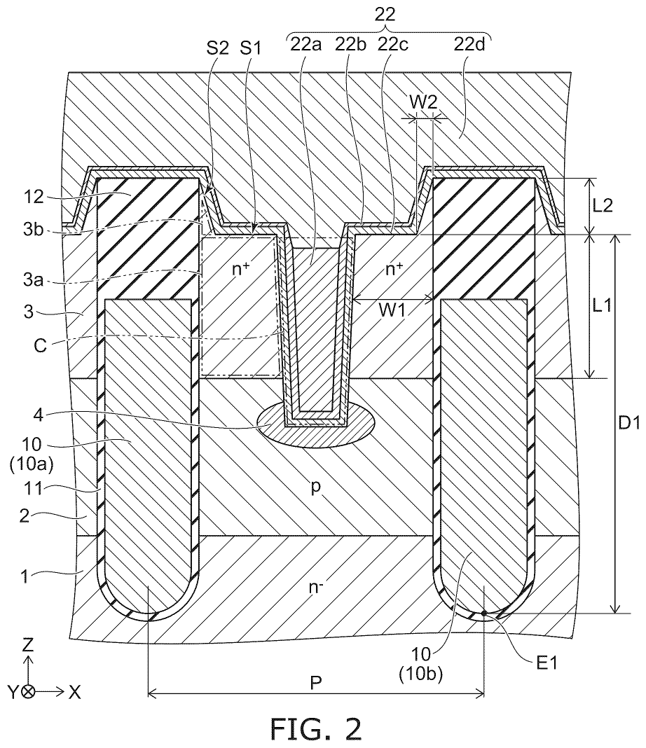

FIG. 2 is an enlarged cross-sectional view of a portion of FIG. 1.

As shown in FIG. 2, the contact portion C includes a first conductive layer 22a, a second conductive layer 22b, and a third conductive layer 22c. The second conductive layer 22b is provided between the first conductive layer 22a and the p-type base region 2, and between the first conductive layer 22a and the n⁺-type source region 3. The third conductive layer 22c is provided between the second conductive layer 22b and the p-type base region 2, and between the second conductive layer 22b and the n⁺-type source region 3.

For example, the second conductive layer 22b and the third conductive layer 22c are provided along the surface of the p-type base region 2, the surface of the n⁺-type source region 3, and the surface of the p⁺-type contact region 4. In the contact portion C of the X-Z cross-section, the area of the first conductive layer 22a is greater than the area of the third conductive layer 22c. The area of the first conductive layer 22a may be greater than the area of the second conductive layer 22b.

The first conductive layer 22a includes a first material that is one or more selected from the first group consisting of silicon, carbon, chromium, and lanthanum. The silicon may be monocrystalline silicon or polysilicon. The first conductive layer 22a may include a compound of silicon and carbon. When silicon or carbon is used, impurities are added to reduce the electrical resistivity of the first conductive layer 22a.

The second conductive layer 22b includes a second material that is one or more selected from the second group consisting of tungsten and molybdenum. The third conductive layer 22c includes a third material that is one or more selected from the third group consisting of titanium and cobalt.

The coefficient of thermal expansion of the first material is less than the coefficient of thermal expansion of the second material and less than the coefficient of thermal expansion of the third material. Therefore, the coefficient of thermal expansion of the first conductive layer 22a is less than the coefficient of thermal expansion of the second conductive layer 22b and less than the coefficient of thermal expansion of the third conductive layer 22c.

For example, the coefficient of thermal expansion of polysilicon to which impurities are added is about 3.0×10⁻⁶/K. The coefficient of thermal expansion of chromium is about 4.5×10⁻⁶/K. The coefficient of thermal expansion of tungsten is about 5.0×10⁻⁶/K. The coefficient of thermal expansion of molybdenum is about 5.5×10⁻⁶/K. The coefficient of thermal expansion of titanium or titanium nitride is about 8.5×10⁻⁶/K. The coefficient of thermal expansion of cobalt is about 13×10⁻⁶/K.

The electrical resistivity of the second material is less than the electrical resistivity of the first material and less than the electrical resistivity of the third material. Therefore, the electrical resistivity of the second conductive layer 22b is less than the electrical resistivity of the first conductive layer 22a and less than the electrical resistivity of the third conductive layer 22c.

For example, the electrical resistivity of chromium is about 13×10⁻⁸ Ω·m. The electrical resistivity of tungsten is about 5.5×10⁻⁸ Ω·m. The electrical resistivity of molybdenum is about 5.5×10⁻⁸ Ω·m. The electrical resistivity of titanium or titanium nitride is about 45×10⁻⁸ Ω·m. The electrical resistivity of cobalt is about 5.8×10⁻⁸ Ω·m. The electrical resistivity of polysilicon depends on the concentration of impurities added. As an example, the n-type impurity concentration or the p-type impurity concentration is not less than 1.0×10¹⁸ atoms/cm³ and not more than 1.0×10²¹ atoms/cm³. In this case, the electrical resistivity of polysilicon is about 1.0×10⁻⁶ to 1.0×10⁻³ Ω·m.

Titanium or titanium nitride has a barrier function to the semiconductor materials included in the semiconductor regions. By providing the third conductive layer 22c, it is possible to suppress the diffusion of the semiconductor materials from the semiconductor regions to the source electrode 22, and the reliability of the semiconductor device 100 can be improved.

Each of the first to third conductive layers may be composed of multiple layers. For example, the third conductive layer 22c may be composed of a titanium layer and a titanium nitride layer provided thereon.

As shown in FIG. 2, the second conductive layer 22b and the third conductive layer 22c may also be provided in a portion other than the contact portion C. For example, the second conductive layer 22b and the third conductive layer 22c are provided along the upper surface of the n⁺-type source region 3 and the upper surface of the second insulating layer 12. The source electrode 22 further includes a fourth conductive layer 22d located on the contact portion C. The fourth conductive layer 22d is located on the first conductive layer 22a, the second conductive layer 22b, and the third conductive layer 22c.

The fourth conductive layer 22d includes a fourth material that is one or more selected from the fourth group consisting of aluminum and copper. The electrical resistivity of the fourth material is less than the electrical resistivity of each of the first to third materials. Therefore, the electrical resistivity of the fourth conductive layer 22d is less than the electrical resistivity of each of the first conductive layer 22a to the third conductive layers 22c. By providing the fourth conductive layer 22d, the electrical resistivity of the source electrode 22 can be reduced. The coefficient of thermal expansion of the fourth material is greater than the coefficient of thermal expansion of the first material. The coefficient of thermal expansion of the fourth material may be greater than the coefficient of thermal expansion of the second material and may be greater than the coefficient of thermal expansion of the third material.

In a case where the second conductive layer 22b is provided in a portion other than the contact portion C, the thickness of the second conductive layer 22b provided in the portion other than the contact portion C may be less than the thickness of the second conductive layer 22b included in the contact portion C. For example, the thickness of the second conductive layer 22b in the Z-direction between the n⁺-type source region 3 and the fourth conductive layer 22d is less than the thickness of the second conductive layer 22b in the X-direction between the n⁺-type source region 3 and the first conductive layer 22a.

As shown in FIG. 2, the n⁺-type source region 3 may include a first portion 3a and a second portion 3b. The first portion 3a is in contact with the p-type base region 2. The first portion 3a is located between the gate electrode 10 and the contact portion C in the X-direction, and between the second insulating layer 12 and the contact portion C. The second portion 3b is located on the first portion 3a and is in contact with the second insulating layer 12.

The first portion 3a has an upper surface S1. The upper surface S1 is in contact with the source electrode 22 in the Z-direction. The second portion 3b has an inclined surface S2. The inclined surface S2 is in contact with the source electrode 22 and is inclined with respect to the Z-direction. For example, the inclination of the upper surface S1 with respect to the X-direction is not less than 0 degrees and not more than 15 degrees. The inclination of the inclined surface S2 with respect to the X-direction is more than 15 degrees and not more than 85 degrees. The inclination of at least a portion of the inclined surface S2 with respect to the X-direction is not less than 60 degrees.

The width W2 of the second portion 3b is less than the width W1 of the first portion 3a. The “width” is the length in the X-direction. For example, the width W1 is measured at the height of the upper end of the gate electrode 10. The “height” is the position in the Z-direction. The width W2 is measured at the height of the boundary between the upper surface S1 and the inclined surface S2.

The length L2 in the Z-direction of the second portion 3b is less than the length L1 in the Z-direction of the first portion 3a. The length L2 may be not more than 0.5 times the length L1, and may be not more than 0.3 times the length L1.

For example, the distance D1 in the Z-direction from the upper surface S1 to the lower end E1 of the gate electrode 10 is not less than 600 nm and not more than 1200 nm. The pitch P of the multiple gate electrodes 10 is not less than 450 nm and not more than 1000 nm. The pitch P corresponds to the distance between the center in the X-direction of a first gate electrode 10a and the center in the X-direction of a second gate electrode 10b. The first gate electrode 10a is one of multiple gate electrodes 10. The second gate electrode 10b is another one of the multiple gate electrodes 10 and is adjacent to the first gate electrode 10a in the X-direction.

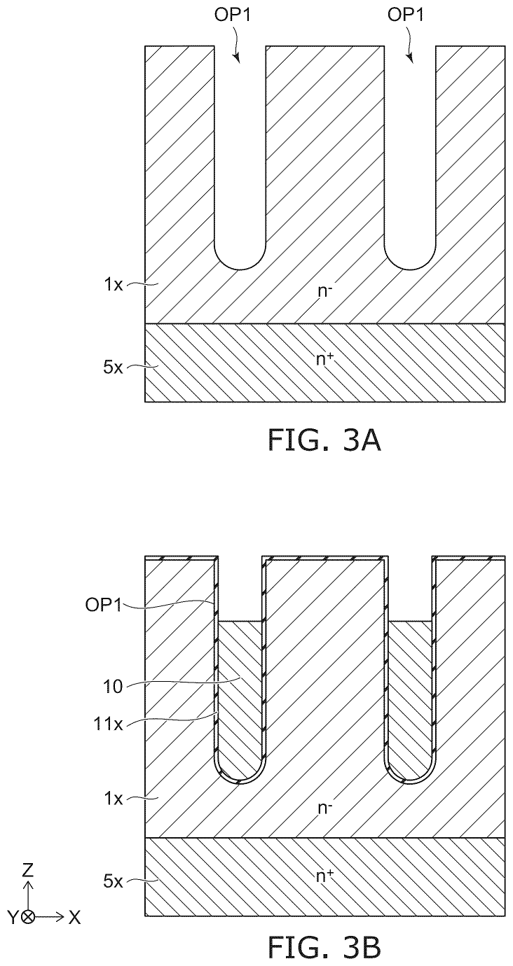

FIGS. 3A, 3B, 4A, 4B, 5A, 5B, 6A, 6B, and 7 are cross-sectional views illustrating a method for manufacturing the semiconductor device according to the embodiment.

First, a semiconductor substrate including an n⁺-type semiconductor layer 5x and an n⁻-type semiconductor layer 1x is prepared. The n⁻-type semiconductor layer 1x is provided on the n⁺-type semiconductor layer 5x. As shown in FIG. 3A, multiple openings OP1 are formed on the upper surface of the n⁻-type semiconductor layer 1x by photolithography and reactive ion etching (RIE). The multiple openings OP1 are separated from each other in the X-direction, and each opening OP1 extends in the Y-direction.

An insulating layer 11x is formed along the surface of the n⁻-type semiconductor layer 1x by thermal oxidation. A conductive layer is formed on the insulating layer 11x by chemical vapor deposition (CVD). The conductive layer includes, for example, polysilicon. The openings OP1 are filled with the conductive layer. The upper surface of the conductive layer is etched by wet etching. As a result, as shown in FIG. 3B, the conductive layer is separated into multiple parts, and the gate electrode 10 is formed inside each opening OP1.

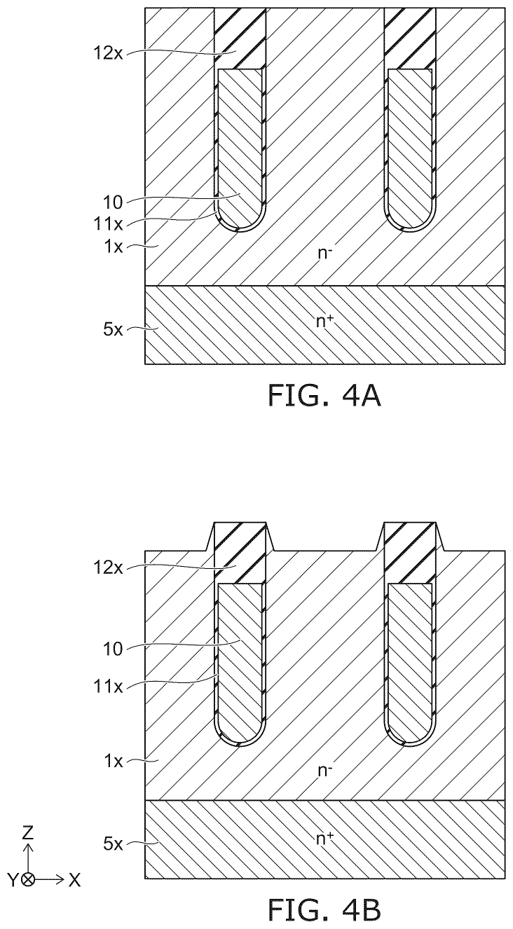

An insulating layer 12x is formed on the gate electrode 10 by CVD. The openings OP1 are filled with the insulating layer 12x. Chemical dry etching (CDE) is performed until the upper surface of the n⁻-type semiconductor layer 1x is exposed. As a result, as shown in FIG. 4A, a portion of the insulating layer 11x and a portion of the insulating layer 12x are removed, and the upper surface of the n⁻-type semiconductor layer 1x is exposed.

A portion of the n⁻-type semiconductor layer 1x between the insulating layers 12x is removed by CDE. In the CDE process, a gas with a higher etching rate for the semiconductor than for the insulating layer is selected. For example, HBr (hydrogen bromide) is used as the gas. When CDE is performed, there is a difference in etching rate between the portion in the vicinity of the insulating layer 12x and the portion away from the insulating layer 12x. In the vicinity of the insulating layer 12x, the n⁻-type semiconductor layer 1x is more difficult to remove. As a result, as shown in FIG. 4B, the upper surface of the portion in the vicinity of the insulating layer 12x is inclined. The upper surface of the portion in the vicinity of the insulating layer 12x is located higher than the upper surface of the portion away from the insulating layer 12x.

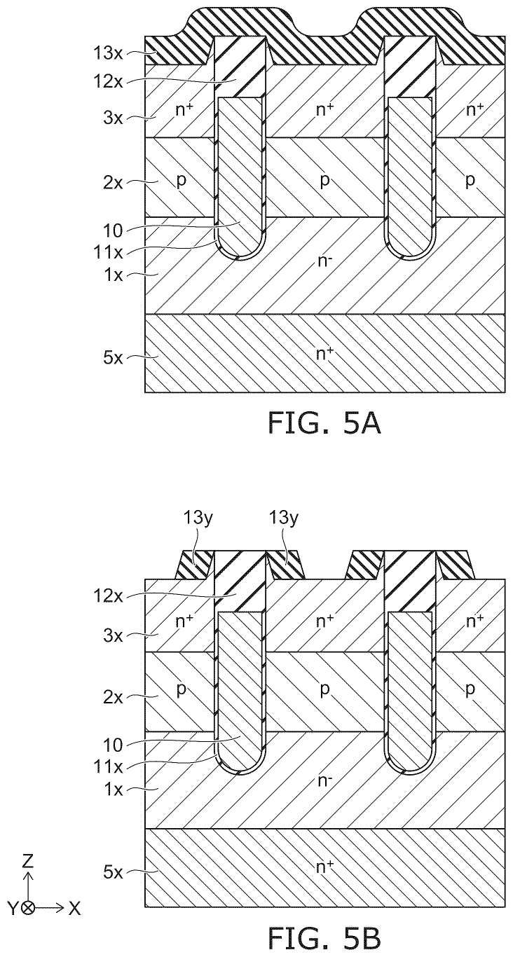

P-type impurities and n-type impurities are sequentially ion-implanted to the upper surface of the n⁻-type semiconductor layer 1x to form a p-type semiconductor region 2x and an n⁺-type semiconductor region 3x. As shown in FIG. 5A, an insulating layer 13x covering the n⁺-type semiconductor region 3x and the insulating layer 12x is formed by CVD. For example, the insulating layer 13x includes an insulating material such as silicon oxide or silicon nitride. As long as it can be used as a mask when etching the semiconductor layer, the material of the insulating layer 13x can be changed as appropriate.

A portion of the insulating layer 13x is located on both ends in the X-direction of the n⁺-type semiconductor region 3x. Another portion of the insulating layer 13x is located on the center in the X-direction of the n⁺-type semiconductor region 3x. The thickness (the dimension in the Z-direction) of the portion of the insulating layer 13x is greater than the thickness of the other portion of the insulating layer 13x.

A portion of the insulating layer 13x is removed, by anisotropic etching, until a portion of the upper surface of the n⁺-type semiconductor region 3x is exposed. At this time, as shown in FIG. 5B, the thinner portion of the insulating layer 13x is removed, while the thicker portion of the insulating layer 13x remains. As a result, the insulating layer 13x remains on each end of the n⁺-type semiconductor region 3x, and other portions of the insulating layer 13x are removed. As a result, a mask 13y made from the insulating layer 13x is formed. The mask 13y covers the vicinity of the insulating layer 12x in the n⁺-type semiconductor region 3x. The center portion in the X-direction of the n⁺-type semiconductor region 3x is exposed.

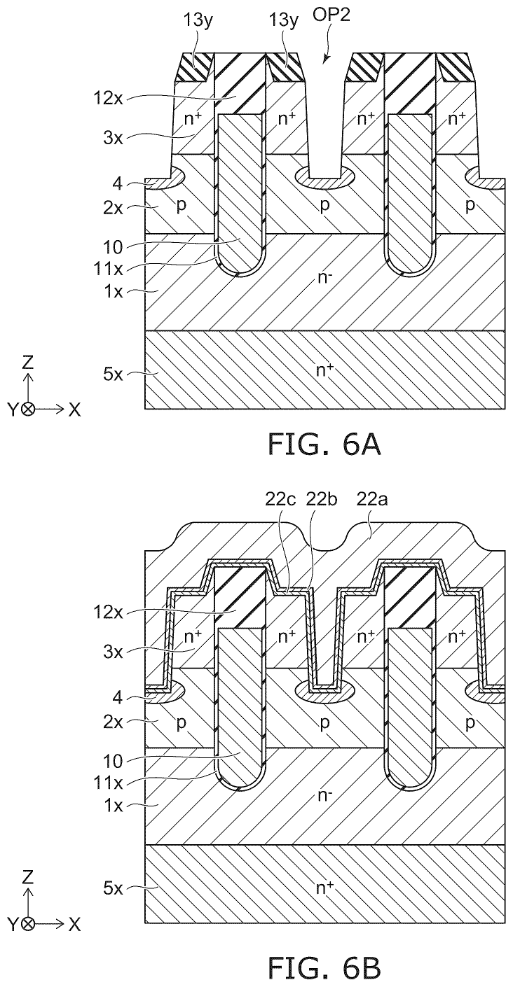

A portion of the n⁺-type semiconductor region 3x and a portion of the p-type semiconductor region 2x are removed by RIE using the mask 13y. As a result, an opening OP2 is formed. As shown in FIG. 6A, through the opening OP2, p-type impurities are ion-implanted to the bottom surface of the opening OP2 to form the p⁺-type contact region 4.

The mask 13y is removed. The third material is deposited by sputtering onto the surface of the p-type semiconductor region 2x and the surface of the n⁺-type semiconductor region 3x to form the third conductive layer 22c. The second material is deposited by sputtering onto the third conductive layer 22c to form the second conductive layer 22b. As shown in FIG. 6B, the first material is deposited on the second conductive layer 22b to form the first conductive layer 22a which fills the opening OP2.

When the first conductive layer 22a includes monocrystalline silicon, the first conductive layer 22a is formed by epitaxial growth. When the first conductive layer 22a includes polysilicon or carbon, the first conductive layer 22a is formed by CVD. When the first conductive layer 22a includes lanthanum or chromium, the first conductive layer 22a is formed by sputtering or vapor deposition.

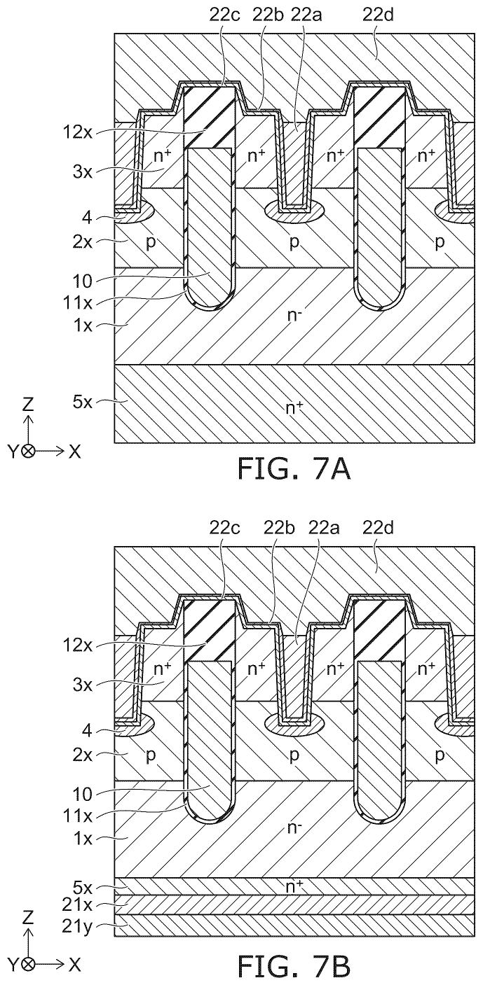

The first conductive layer 22a is selectively removed by CDE or wet etching. The etching amount of the second conductive layer 22b is significantly smaller compared to the etching amount of the first conductive layer 22a. As a result, the first conductive layer 22a remains inside each opening OP2. In addition, by the etching process, the thickness of the second conductive layer 22b provided outside the opening OP2 becomes less than the thickness of the second conductive layer 22b provided inside the opening OP2. As shown in FIG. 7A, the fourth conductive layer 22d is formed by sputtering onto the first conductive layer 22a and the third conductive layer 22c.

The lower surface of the n⁺-type semiconductor layer 5x is ground until the n⁺-type semiconductor layer 5x reaches a predetermined thickness. As shown in FIG. 7B, a metal layer 21x is formed on the lower surface of the ground n⁺-type semiconductor layer 5x by sputtering. The metal layer 21x includes titanium. A metal layer 21y is formed on the metal layer 21x by plating. The metal layer 21y includes silver. Alternatively, the metal layer 21y may include a eutectic of gold and tin. According to the above steps, the semiconductor device 100 according to the embodiment is manufactured.

The n⁻-type semiconductor layer 1x shown in FIG. 7B corresponds to the n⁻-type drift region 1 shown in FIG. 1. The p-type semiconductor region 2x corresponds to the p-type base region 2. The n⁺-type semiconductor region 3x corresponds to the n⁺-type source region 3. The n⁺-type semiconductor layer 5x corresponds to the n⁺-type drain region 5. The insulating layer 11x corresponds to the first insulating layer 11. The insulating layer 12x corresponds to the second insulating layer 12. The metal layers 21x and 21y correspond to the drain electrode 21.

Advantages of the embodiment will now be described.

The semiconductor device 100 includes a parasitic transistor consisting of the n⁻-type drift region 1, the p-type base region 2, and the n⁺-type source region 3. For example, when the semiconductor device 100 is turned off, carriers (electrons and holes) are generated by avalanche breakdown. Electrons are discharged to the drain electrode 21 through the n⁺-type drain region 5. Holes are discharged to the source electrode 22 through the p-type base region 2 and the p⁺-type contact region 4. At this time, when the electric potential of the p-type base region 2 rises, the parasitic transistor may operate. When the parasitic transistor operates, a large current flows through the semiconductor device 100 and the semiconductor device 100 undergoes breakdown.

In order to suppress the operation of the parasitic transistor, it is desirable that the holes are efficiently discharged to the source electrode 22. By discharging the holes to the source electrode 22, the rise in the electric potential of the p-type base region 2 is suppressed. By providing the contact portion C, the contact area between the p-type base region 2 and the source electrode 22 and the contact area between the p⁺-type contact region 4 and the source electrode 22 are increased. As a result, the rise in the electric potential of the p-type base region 2 is suppressed, and the parasitic transistor is less likely to operate.

On the other hand, the contact portion C includes an electrode material (a metal). The coefficient of thermal expansion of the contact portion C is larger than the coefficient of thermal expansion of a semiconductor region. During the operation of the semiconductor device 100, heat is generated. When the temperature of the semiconductor device 100 rises, stress due to thermal expansion is applied from the contact portion C to each semiconductor region. When stress is repeatedly applied to the semiconductor regions due to temperature cycling, crystal defects may occur in the semiconductor regions. Crystal defects increase the leakage current between the drain electrode 21 and the source electrode 22.

In the embodiment of the present invention, the contact portion C includes the first conductive layer 22a, the second conductive layer 22b, and the third conductive layer 22c. The coefficient of thermal expansion of the first conductive layer 22a is less than the coefficient of thermal expansion of the second conductive layer 22b and less than the coefficient of thermal expansion of the third conductive layer 22c. By providing the first conductive layer 22a, the amount of thermal expansion of the contact portion C can be suppressed and the stress applied to the semiconductor regions can be reduced. In addition, the electrical resistivity of the second conductive layer 22b is less than the electrical resistivity of the first conductive layer 22a and less than the electrical resistivity of the third conductive layer 22c. By providing the second conductive layer 22b, an increase in electrical resistance due to the first conductive layer 22a can be suppressed, and a decrease in the discharge efficiency of the holes can be suppressed. The third conductive layer 22c is provided between each semiconductor region and the second conductive layer 22b and functions as a barrier layer.

According to the embodiment, the coefficient of thermal expansion of the contact portion C can be reduced while suppressing the increase in electrical resistance in the contact portion C. In other words, according to the embodiment, the occurrence of leakage current due to crystal defects can be suppressed while suppressing the operation of the parasitic transistor.

The first material included in the first conductive layer 22a is preferably silicon. This is because silicon has a smaller coefficient of thermal expansion compared to chromium and lanthanum. In addition, compared to chromium and lanthanum, silicon is less likely to cause contamination of the manufacturing apparatus during the formation of the first conductive layer 22a, and it is also easier to fill the opening OP2.

The second material included in the second conductive layer 22b is preferably tungsten. This is because tungsten has a smaller coefficient of thermal expansion compared to molybdenum.

The third material included in the third conductive layer 22c is preferably titanium. This is because titanium has a smaller coefficient of thermal expansion compared to cobalt.

As shown in FIG. 2, the n⁺-type source region 3 may include the first portion 3a and the second portion 3b. For example, the n-type impurity concentration in the second portion 3b is less than the n-type impurity concentration in the first portion 3a. This is because the n-type impurities in the second portion 3b diffuse more easily into the surroundings compared to those in the first portion 3a, since the width W2 of the second portion 3b is less than the width W1 of the first portion 3a. In this case, the electrical resistivity of the second portion 3b is greater than the electrical resistivity of the first portion 3a.

From the viewpoint of reducing the on-resistance, the second portion 3b is not preferable. On the other hand, the electrical resistivity of the second portion 3b is greater than the electrical resistivity of the first portion 3a. The voltage drop when the current flows through the second portion 3b is greater than the voltage drop when the current flows through the first portion 3a. For example, when the semiconductor device 100 is in a short-circuit state, a large current flows through the semiconductor device 100. At this time, the voltage drop increases because of the second portion 3b, which helps to suppress the current flowing through the semiconductor device 100. By providing the second portion 3b that is narrower than the first portion 3a, it is possible to reduce the current density in the short-circuit state while suppressing an increase in the on-resistance of the semiconductor device 100.

In the semiconductor device 100, the pitch P is preferably small. The smaller the pitch P, the greater the number of gate electrodes 10 arranged per unit area. As a result, the channel density increases. As the channel density increases, the number of current path in the on-state increases. Therefore, the on-resistance of the semiconductor device 100 can be reduced. For example, from the viewpoint of reducing the on-resistance, the pitch P is preferably not less than 450 nm and not more than 1000 nm.

On the other hand, the greater the number of gate electrodes 10 arranged per unit area, the greater the stress applied to the semiconductor regions from the gate electrodes 10, the first insulating layers 11, the second insulating layers 12, etc. As a result, crystal defects are more likely to occur in the semiconductor regions. According to the embodiment, even if the pitch P is small, the stress applied from the contact portion C to the semiconductor regions can be reduced. The occurrence of crystal defects in the semiconductor regions can be suppressed. Therefore, the embodiment is suitable for semiconductor devices with the pitch P of 1000 nm or less.

In order to stabilize the operation of the semiconductor device 100, the depth of the gate electrode 10 (the distance D1 shown in FIG. 2) is preferably not less than 600 nm. On the other hand, the greater the distance D1, the greater the volume of the gate electrode 10. When the thickness in the Z-direction of the semiconductor region (the distance between the drain electrode 21 and the source electrode 22) is constant, the larger the volume of the gate electrode 10, the larger the proportion of the volume of the gate electrode 10. The coefficient of thermal expansion of the material (for example, silicon) included in the semiconductor region is different from the coefficient of thermal expansion of the material (for example, polysilicon) included in the gate electrode 10. In the manufacturing process of the semiconductor device 100, multiple heat treatments are performed. As the proportion of the volume of the gate electrode 10 increases, the stress generated during the heating and cooling increases, which may cause crystal defects. Therefore, from the viewpoint of reducing crystal defects, it is preferable that the distance D1 is not more than 1200 nm. In addition, since the occurrence of crystal defects can be suppressed according to the embodiment of the present invention, crystal defects in the semiconductor device 100 can be sufficiently reduced even when the distance D1 is not less than 600 nm.

When the second conductive layer 22b is further provided in a portion other than the contact portion C as shown in FIG. 2, the thickness of the second conductive layer 22b provided in the portion other than the contact portion C is preferably less than the thickness of the second conductive layer 22b included in the contact portion C. When the thickness of the source electrode 22 is constant, the smaller the thickness of the second conductive layer 22b, the greater the thickness of the fourth conductive layer 22d. The electrical resistivity of the fourth conductive layer 22d is less than the electrical resistivity of the second conductive layer 22b. In the source electrode 22, the greater the thickness proportion of the fourth conductive layer 22d, the lower the electrical resistance of the source electrode 22, and the lower the on-resistance of the semiconductor device 100.

### First Modification

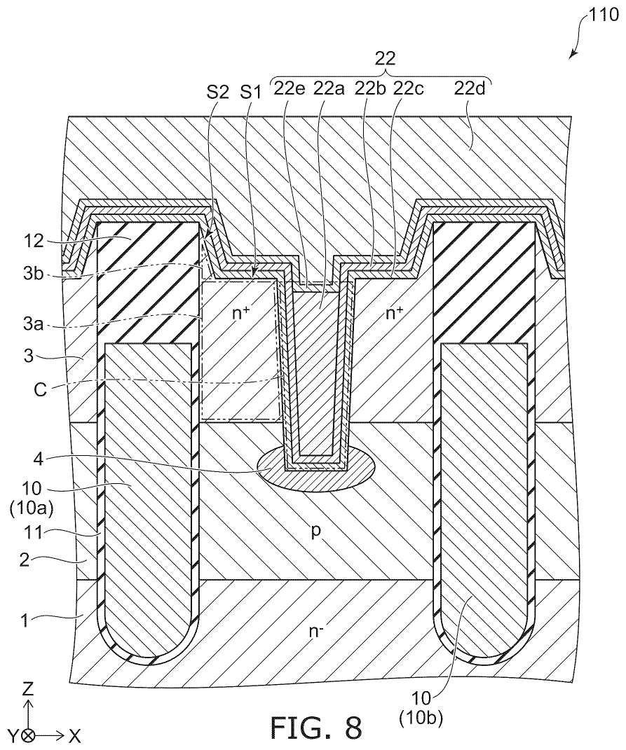

FIG. 8 is a cross-sectional view illustrating a portion of a semiconductor device according to a first modification of the embodiment.

In the semiconductor device 110 shown in FIG. 8, the source electrode 22 further includes a fifth conductive layer 22e. The other configurations of the semiconductor device 110 may be the same as those of the semiconductor device 100.

The fifth conductive layer 22e is provided between the first conductive layer 22a and the fourth conductive layer 22d. The contact portion C may include the fifth conductive layer 22e, or the fifth conductive layer 22e may be located higher than the contact portion C. As shown in FIG. 8, the fifth conductive layer 22e may be further provided between the second conductive layer 22b and the fourth conductive layer 22d.

The fifth conductive layer 22e includes a fifth material that is one or more selected from the fifth group consisting of tungsten and molybdenum. The fifth material may be the same as the second material or different from the second material.

When the first conductive layer 22a and the fourth conductive layer 22d are in contact, the first material included in the first conductive layer 22a and the fourth material included in the fourth conductive layer 22d may react. For example, when the first conductive layer 22a includes silicon and the fourth conductive layer 22d includes aluminum, aluminum can diffuse into the silicon layer.

The fifth material has a barrier function similar to the third material (titanium or cobalt). By providing the fifth conductive layer 22e including the fifth material between the first conductive layer 22a and the fourth conductive layer 22d, the reaction between the first material and the fourth material can be suppressed. In addition, the coefficient of thermal expansion of the fifth material is less than the coefficient of thermal expansion of the third material, and the electrical resistivity of the fifth material is less than the electrical resistivity of the third material. Therefore, even when the fifth conductive layer 22e is provided, an increase in the coefficient of thermal expansion and an increase in the electrical resistivity of the source electrode 22 can be suppressed.

### Second Modification

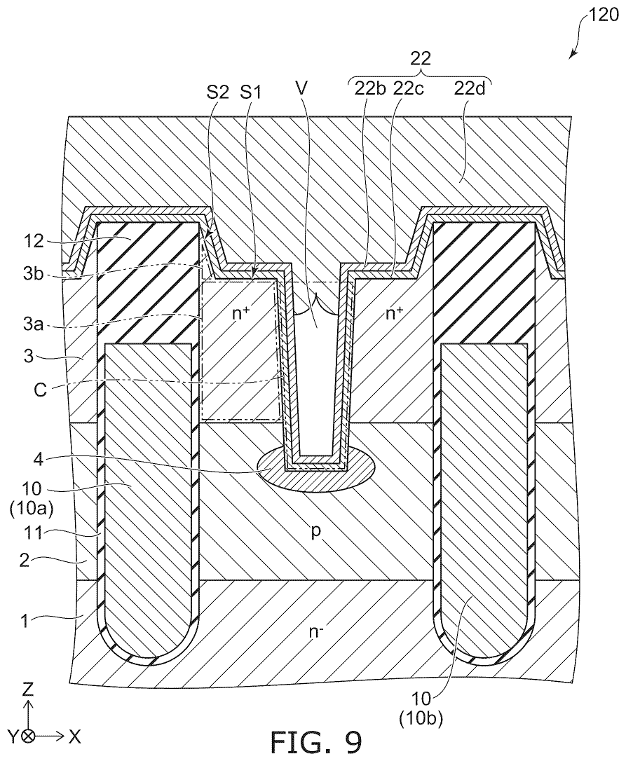

FIG. 9 is a cross-sectional view illustrating a portion of the semiconductor device according to a second modification of the embodiment.

In the semiconductor device 120 shown in FIG. 9, the contact portion C includes a void V. The contact portion C is not provided with the first conductive layer 22a. The second conductive layer 22b and the third conductive layer 22c are provided between the void V and the p-type base region 2 and between the void V and the n⁺-type source region 3. The other configurations of the semiconductor device 120 may be the same as those of the semiconductor device 100.

For example, in the step shown in FIG. 6B, after forming the third conductive layer 22c and the second conductive layer 22b, the fourth conductive layer 22d can be formed at a high deposition rate to form the void V. By increasing the deposition rate, the upper portion of the opening OP2 is closed in a state where the opening OP2 is not filled with materials.

When heat is generated in the semiconductor device 120, the second conductive layer 22b and the third conductive layer 22c can thermally expand toward the void V. Therefore, according to the semiconductor device 120, the stress applied to each semiconductor region from the contact portion C due to thermal expansion can be reduced. According to the semiconductor device 120, the occurrence of crystal defects can be further suppressed compared to the semiconductor device 100.

The pressure in the void V is, for example, below atmospheric pressure. Since the pressure of the void V is low, the second conductive layer 22b and the third conductive layer 22c are more likely to thermally expand toward the void V. As a result, the stress applied from the contact portion C to each semiconductor region can be further reduced.

The void V functions as an insulator. Therefore, from the viewpoint of reducing the electrical resistance of the contact portion C, the semiconductor device 100 is preferable to the semiconductor device 120.

### Third Modification

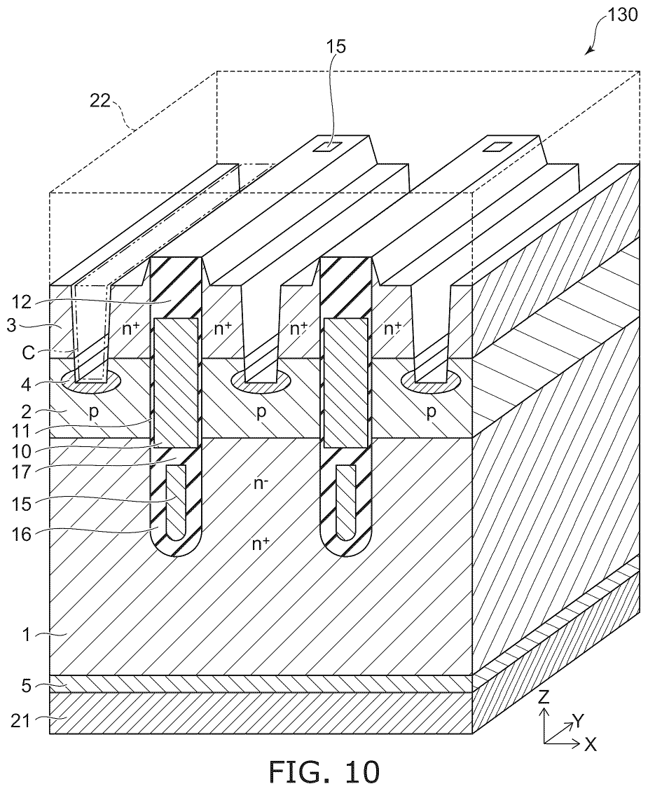

FIG. 10 is a cross-sectional view illustrating a portion of a semiconductor device according to a third modification of the embodiment.

The semiconductor device 130 shown in FIG. 10 further includes a field plate electrode 15 (an FP electrode, a third electrode) and an insulating layer 16 compared to the semiconductor device 100. The other configurations of the semiconductor device 130 may be the same as those of the semiconductor device 100.

The FP electrode 15 is provided in the n⁻-type drift region 1 via an insulating layer 16. The gate electrode 10 is located on the FP electrode 15 via an insulating layer 17. The FP electrode 15 extends in the Y-direction.

For example, the end of the FP electrode 15 in the Y-direction is raised upward and connected to the source electrode 22. Alternatively, the insulating layer 17 may be omitted, and the FP electrode 15 may be connected to the gate electrode 10.

The FP electrode 15 includes a conductive material such as polysilicon. The insulating layers 16 and 17 include an insulating material such as silicon oxide, silicon nitride, or silicon oxynitride.

When the semiconductor device 130 switches to the off-state, the positive voltage applied to the drain electrode 21 with respect to the source electrode 22 increases. The electric potential of the FP electrode 15 is substantially the same as the electric potential of the gate electrode 10 or the source electrode 22. A potential difference occurs between the FP electrode 15 and the n⁻-type drift region 1, which is electrically connected to the drain electrode 21. As a result, the depletion layer spreads from the interface between the insulating layer 16 and the n⁻-type drift region 1 toward the n⁻-type drift region 1. The expansion of the depletion layer allows the breakdown voltage of the semiconductor device 130 to increase. Alternatively, while maintaining the breakdown voltage of the semiconductor device 130, the n-type impurity concentration in the n⁻-type drift region 1 can be increased, and the on-resistance of the semiconductor device 130 can be reduced.

The embodiments of the present invention include the following features.

### Feature 1

A semiconductor device, comprising:
a first electrode;
a first semiconductor region of a first conductivity type provided on the first electrode;
a second semiconductor region of a second conductivity type provided on the first semiconductor region;
a third semiconductor region of the first conductivity type provided on the second semiconductor region;
a gate electrode facing the second semiconductor region via a first insulating layer in a second direction that is perpendicular to a first direction from the first electrode toward the first semiconductor region; and
a second electrode including a contact portion that is in contact with the third semiconductor region in the second direction, the second electrode provided on the second semiconductor region and the third semiconductor region, the contact portion including
   a first conductive layer,
   a second conductive layer provided between the first conductive layer and the second semiconductor region and between the first conductive layer and the third semiconductor region, and
   a third conductive layer provided between the second conductive layer and the second semiconductor region and between the second conductive layer and the third semiconductor region,
a coefficient of thermal expansion of the first conductive layer being less than a coefficient of thermal expansion of the second conductive layer and less than a coefficient of thermal expansion of the third conductive layer, an electrical resistivity of the second conductive layer being less than an electrical resistivity of the first conductive layer and less than an electrical resistivity of the third conductive layer.

### Feature 2

The semiconductor device according to feature 1, wherein
the second electrode includes a fourth conductive layer located on the contact portion, and
an electrical resistivity of the fourth conductive layer is less than the electrical resistivity of the first conductive layer and less than the electrical resistivity of the second conductive layer.

### Feature 3

A semiconductor device, comprising:
a first electrode;
a first semiconductor region of a first conductivity type provided on the first electrode;
a second semiconductor region of a second conductivity type provided on the first semiconductor region;
a third semiconductor region of the first conductivity type provided on the second semiconductor region;
a gate electrode facing the second semiconductor region via a first insulating layer in a second direction that is perpendicular to a first direction from the first electrode toward the first semiconductor region; and
a second electrode including a contact portion that is in contact with the third semiconductor region in the second direction, the second electrode provided on the second semiconductor region and the third semiconductor region, the contact portion including
   a first conductive layer including a first material that is one or more selected from the first group consisting of silicon, carbon, chromium, and lanthanum,
   a second conductive layer provided between the first conductive layer and the second semiconductor region and between the first conductive layer and the third semiconductor region, the second conductive layer including a second material that is one or more selected from the second group consisting of tungsten and molybdenum, and
   a third conductive layer provided between the second conductive layer and the second semiconductor region and between the second conductive layer and the third semiconductor region, the third conductive layer including a third material that is one or more selected from the third group consisting of titanium and cobalt.

### Feature 4

The semiconductor device according to feature 3, wherein
the second electrode includes a fourth conductive layer located on the contact portion, and
the fourth conductive layer includes a fourth material that is one or more selected from the fourth group consisting of aluminum and copper.

### Feature 5

The semiconductor device according to feature 4, wherein
the second electrode includes a fifth conductive layer located between the contact portion and the fourth conductive layer, and
the fifth conductive layer includes a fifth material that is one or more selected from the fifth group consisting of tungsten and molybdenum.

### Feature 6

The semiconductor device according to any one of features 3 to 5, wherein
the first material is silicon,
the second material is tungsten, and
the third material is titanium.

### Feature 7

A semiconductor device, comprising:
a first electrode;
a first semiconductor region of a first conductivity type provided on the first electrode;
a second semiconductor region of a second conductivity type provided on the first semiconductor region;
a third semiconductor region of the first conductivity type provided on the second semiconductor region;
a gate electrode facing the second semiconductor region via a first insulating layer in a second direction that is perpendicular to a first direction from the first electrode toward the first semiconductor region; and
a second electrode including a contact portion that is in contact with the third semiconductor region in the second direction, the second electrode provided on the second semiconductor region and the third semiconductor region, the contact portion including a void.

### Feature 8

The semiconductor device according to any one of features 1 to 7, further comprising a second insulating layer provided between the gate electrode and the second electrode in the first direction,
the third semiconductor region includes
   a first portion being in contact with the second semiconductor region, and
   a second portion provided on the first portion and being in contact with the second insulating layer, a length in the second direction of the second portion being less than a length in the second direction of the first portion,
an inclination of an upper surface of the first portion with respect to the second direction being not less than 0 degrees and not more than 15 degrees,
the second portion having an inclined surface,
an inclination of the inclined surface with respect to the second direction being more than 15 degrees and not more than 85 degrees.

### Feature 9

The semiconductor device according to feature 8, wherein
a plurality of the gate electrodes are provided in the second direction,
the plurality of gate electrodes include a first gate electrode and a second gate electrode adjacent to each other in the second direction,
a distance between a center of the first gate electrode in the second direction and a center of the second gate electrode in the second direction is not less than 450 nm and not more than 1000 nm, and
a distance in the first direction from an upper surface of the first portion to a lower end of the first gate electrode is not less than 600 nm and not more than 1200 nm.

### Feature 10

The semiconductor device according to any one of features 1 to 9, further comprising a third electrode provided in the first semiconductor region via an insulating layer,
the gate electrode is positioned on the third electrode, and
the third electrode is electrically connected to the second electrode or the gate electrode

The embodiments described above may be combined and implemented as appropriate. For example, the FP electrode 15 may be provided in the semiconductor device 110 or 120.

In the specification, “or” shows that “at least one” of items listed in the sentence can be adopted.

In the embodiments above, the relative levels of the impurity concentrations between the semiconductor regions can be confirmed using, for example, a scanning capacitance microscope (SCM). The carrier concentration in each semiconductor region can be considered to be equal to the activated impurity concentration in each semiconductor region. Accordingly, the relative levels of the carrier concentrations between the semiconductor regions also can be confirmed using SCM. The impurity concentration in each semiconductor region can be measured, for example, using secondary ion mass spectrometry (SIMS).

In the source electrode 22, the identification of the first to fifth conductive layers 22a to 22e can be performed using energy-dispersive X-ray spectroscopy (EDX). For example, the semiconductor device is cut along the X-Z plane. The cross-section is observed using a scanning electron microscope (SEM) to confirm the contact portion C of the source electrode 22. By performing spot analysis of the contact portion C using EDX, the composition of each part of the contact portion C can be measured. Based on the measurement results, the presence of the first to fifth conductive layers 22a to 22e can be determined.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Moreover, above-mentioned embodiments can be combined mutually and can be carried out.

What is claimed is:

1. A semiconductor device, comprising:
a first electrode;
a first semiconductor region of a first conductivity type provided on the first electrode;
a second semiconductor region of a second conductivity type provided on the first semiconductor region;
a third semiconductor region of the first conductivity type provided on the second semiconductor region;
a gate electrode facing the second semiconductor region via a first insulating layer in a second direction that is perpendicular to a first direction from the first electrode toward the first semiconductor region; and
a second electrode including a contact portion that is in contact with the third semiconductor region in the second direction, the second electrode provided on the second semiconductor region and the third semiconductor region, the contact portion including
a first conductive layer,
a second conductive layer provided between the first conductive layer and the second semiconductor region and between the first conductive layer and the third semiconductor region, and
a third conductive layer provided between the second conductive layer and the second semiconductor region and between the second conductive layer and the third semiconductor region,
a coefficient of thermal expansion of the first conductive layer being less than a coefficient of thermal expansion of the second conductive layer and less than a coefficient of thermal expansion of the third conductive layer, an electrical resistivity of the second conductive layer being less than an electrical resistivity of the first conductive layer and less than an electrical resistivity of the third conductive layer.

2. The semiconductor device according to claim 1, wherein
the second electrode includes a fourth conductive layer located on the contact portion, and
an electrical resistivity of the fourth conductive layer is less than the electrical resistivity of the first conductive layer and less than the electrical resistivity of the second conductive layer.

3. The semiconductor device according to claim 1, further comprising a second insulating layer provided between the gate electrode and the second electrode in the first direction,
the third semiconductor region includes
a first portion being in contact with the second semiconductor region, and
a second portion provided on the first portion and being in contact with the second insulating layer, a length in the second direction of the second portion being less than a length in the second direction of the first portion,
an inclination of an upper surface of the first portion with respect to the second direction being not less than 0 degrees and not more than 15 degrees,
the second portion having an inclined surface,
an inclination of the inclined surface with respect to the second direction being more than 15 degrees and not more than 85 degrees.

4. The semiconductor device according to claim 3, wherein
a plurality of the gate electrodes are provided in the second direction,
the plurality of gate electrodes include a first gate electrode and a second gate electrode adjacent to each other in the second direction,
a distance between a center of the first gate electrode in the second direction and a center of the second gate electrode in the second direction is not less than 450 nm and not more than 1000 nm, and
a distance in the first direction from an upper surface of the first portion to a lower end of the first gate electrode is not less than 600 nm and not more than 1200 nm.

5. The semiconductor device according to claim 1, further comprising a third electrode provided in the first semiconductor region via an insulating layer,
the gate electrode is positioned on the third electrode, and
the third electrode is electrically connected to the second electrode or the gate electrode.

6. A semiconductor device, comprising:
a first electrode;
a first semiconductor region of a first conductivity type provided on the first electrode;
a second semiconductor region of a second conductivity type provided on the first semiconductor region;
a third semiconductor region of the first conductivity type provided on the second semiconductor region;
a gate electrode facing the second semiconductor region via a first insulating layer in a second direction that is perpendicular to a first direction from the first electrode toward the first semiconductor region; and
a second electrode including a contact portion that is in contact with the third semiconductor region in the second direction, the second electrode provided on the second semiconductor region and the third semiconductor region, the contact portion including
a first conductive layer including a first material that is one or more selected from the first group consisting of silicon, carbon, chromium, and lanthanum,
a second conductive layer provided between the first conductive layer and the second semiconductor region and between the first conductive layer and the third semiconductor region, the second conductive layer including a second material that is one or more selected from the second group consisting of tungsten and molybdenum, and
a third conductive layer provided between the second conductive layer and the second semiconductor region and between the second conductive layer and the third semiconductor region, the third conductive layer including a third material that is one or more selected from the third group consisting of titanium and cobalt.

7. The semiconductor device according to claim 6, wherein
the second electrode includes a fourth conductive layer located on the contact portion, and
the fourth conductive layer includes a fourth material that is one or more selected from the fourth group consisting of aluminum and copper.

8. The semiconductor device according to claim 7, wherein
the second electrode includes a fifth conductive layer located between the contact portion and the fourth conductive layer, and
the fifth conductive layer includes a fifth material that is one or more selected from the fifth group consisting of tungsten and molybdenum.

9. The semiconductor device according to claim 6, wherein
the first material is silicon,
the second material is tungsten, and
the third material is titanium.

10. The semiconductor device according to claim 1, further comprising a second insulating layer provided between the gate electrode and the second electrode in the first direction,
the third semiconductor region includes
a first portion being in contact with the second semiconductor region, and
a second portion provided on the first portion and being in contact with the second insulating layer, a length in the second direction of the second portion being less than a length in the second direction of the first portion,
an inclination of an upper surface of the first portion with respect to the second direction being not less than 0 degrees and not more than 15 degrees,
the second portion having an inclined surface,
an inclination of the inclined surface with respect to the second direction being more than 15 degrees and not more than 85 degrees.

11. The semiconductor device according to claim 10, wherein
a plurality of the gate electrodes are provided in the second direction,
the plurality of gate electrodes include a first gate electrode and a second gate electrode adjacent to each other in the second direction,
a distance between a center of the first gate electrode in the second direction and a center of the second gate electrode in the second direction is not less than 450 nm and not more than 1000 nm, and
a distance in the first direction from an upper surface of the first portion to a lower end of the first gate electrode is not less than 600 nm and not more than 1200 nm.

12. The semiconductor device according to claim 6, further comprising a third electrode provided in the first semiconductor region via an insulating layer,
the gate electrode is positioned on the third electrode, and
the third electrode is electrically connected to the second electrode or the gate electrode.

13. A semiconductor device, comprising:
a first electrode;
a first semiconductor region of a first conductivity type provided on the first electrode;
a second semiconductor region of a second conductivity type provided on the first semiconductor region;
a third semiconductor region of the first conductivity type provided on the second semiconductor region;
a gate electrode facing the second semiconductor region via a first insulating layer in a second direction that is perpendicular to a first direction from the first electrode toward the first semiconductor region; and
a second electrode including a contact portion that is in contact with the third semiconductor region in the second direction, the second electrode provided on the second semiconductor region and the third semiconductor region, the contact portion including a void.

14. The semiconductor device according to claim 13, further comprising a second insulating layer provided between the gate electrode and the second electrode in the first direction,
the third semiconductor region includes
a first portion being in contact with the second semiconductor region, and
a second portion provided on the first portion and being in contact with the second insulating layer, a length in the second direction of the second portion being less than a length in the second direction of the first portion,
an inclination of an upper surface of the first portion with respect to the second direction being not less than 0 degrees and not more than 15 degrees,
the second portion having an inclined surface,
an inclination of the inclined surface with respect to the second direction being more than 15 degrees and not more than 85 degrees.

15. The semiconductor device according to claim 14, wherein
a plurality of the gate electrodes are provided in the second direction,
the plurality of gate electrodes include a first gate electrode and a second gate electrode adjacent to each other in the second direction,
a distance between a center of the first gate electrode in the second direction and a center of the second gate electrode in the second direction is not less than 450 nm and not more than 1000 nm, and
a distance in the first direction from an upper surface of the first portion to a lower end of the first gate electrode is not less than 600 nm and not more than 1200 nm.

16. The semiconductor device according to claim 13, further comprising a third electrode provided in the first semiconductor region via an insulating layer,
the gate electrode is positioned on the third electrode, and
the third electrode is electrically connected to the second electrode or the gate electrode.
